(19) United States
(12) Patent Application Publication
(10) Pub. No.: US 2025/0125316 A1
(43) Pub. Date: Apr. 17, 2025

(54) MICRO LED DISPLAY PANEL

(71) Applicant: JADE BIRD DISPLAY (SHANGHAI) LIMITED, SHANGHAI (CN)

(72) Inventors: Jin CAO, Shanghai (CN); Jian GUO, Shanghai (CN)

(21) Appl. No.: 18/911,272

(22) Filed: Oct. 10, 2024

(30) Foreign Application Priority Data
Oct. 13, 2023 (WO) PCT/CN2023/124489

(51) Int. Cl. H01L 25/075; H01L 33/04; H01L 33/10; H01L 33/32; H01L 33/58

(52) U.S. Cl. CPC H01L 25/0753; H10H 20/811; H10H 20/814; H10H 20/825; H10H 20/855

(57) ABSTRACT

A micro LED display panel includes a mesa array including a plurality of mesa structures; a top transparent conductive layer formed on a top surface of the mesa array; a reflective isolation layer filled in a space between the adjacent mesa structures, a bottom of the reflective isolation layer being lower than a bottom of the mesa structure; and an integrated circuit (IC) backplane formed at a bottom of the reflective isolation layer.

### CROSS-REFERENCE TO RELATED APPLICATIONS

The present disclosure claims the benefits of priority to PCT Application No. PCT/CN2023/124489, filed on Oct. 13, 2023, which is incorporated herein by reference in its entirety.

### TECHNICAL FIELD

The present disclosure generally relates to micro display technology, and more particularly, to a micro light emitting diode (LED) display panel.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) back panel. Each pixel of the micro LED display panel is formed by one or more micro LEDs. The micro LED display panel can be a mono-color or multi-color panel. In particular, for a multi-color LED panel, each pixel may further include multiple sub-pixels formed by multiple micro LEDs, each of which corresponds to a different color. For example, three micro LEDs respectively corresponding to red, green, and blue colors may be superimposed to form one pixel. The different colors can be mixed to produce a broad array of colors.

Generally, to improve light emission efficiency, a metal reflective layer is provided to reflect light upwards. The metal reflective layer is usually made of Ag, Al, etc., and coated with one or more of Cr, Ni, Pt, Ti, or Au.

### SUMMARY OF THE DISCLOSURE

Embodiments of the present disclosure provide a micro LED display panel. The micro LED display panel includes a mesa array including a plurality of mesa structures; a top transparent conductive layer formed on a top surface of the mesa array; a reflective isolation layer filled in a space between the adjacent mesa structures, a bottom of the reflective isolation layer being lower than a bottom of the mesa structure; and an integrated circuit (IC) backplane formed at a bottom of the reflective isolation layer.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a sectional view of an exemplary micro LED display panel, according to some embodiments of the present disclosure.

FIG. 2 illustrates a structural diagram showing an exemplary DBR (distributed Bragg reflection) structure, according to some embodiments of the present disclosure.

FIG. 3 illustrates a structural diagram showing a sectional view of another exemplary micro LED display panel, according to some embodiments of the present disclosure.

FIG. 4 illustrates a structural diagram showing a top view of an exemplary micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

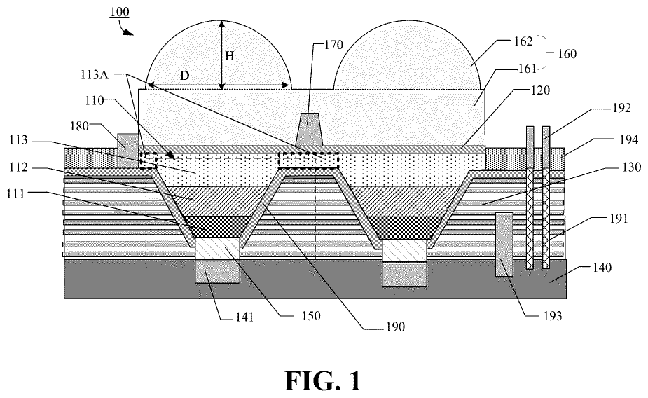

FIG. 1 illustrates a structural diagram showing a sectional view of an exemplary micro LED display panel 100, according to some embodiments of the present disclosure. Referring to FIG. 1, micro LED display panel 100 includes a mesa array including a plurality of mesa structures 110. In this example, two mesa structures 110 are shown only for descriptive purposes. It can be understood that additional mesa structures 110 can be incorporated in a micro LED display panel. In some embodiments, a sidewall of mesa structure 110 is inclined.

As shown in FIG. 1, micro LED display panel 100 further includes a top transparent conductive layer 120 formed on a top surface of the mesa array, and a reflective isolation layer 130 filled in a space between the adjacent mesa structures 110. An integrated circuit (IC) backplane 140 is formed at a bottom of reflective isolation layer 130. A bottom of reflective isolation layer 130 is lower than a bottom of mesa structure 110. Reflective isolation layer 130 is a non-metal layer, which is configured to reflect lights upwards and prevent metal migration. Therefore, there is no metal reflective layer required, which reduces the cost.

Micro LED display panel 100 further includes a group of bottom connecting structures 150. One bottom connecting structure 150 corresponds to one mesa structure 110. Bottom connecting structure 150 is provided at a bottom of mesa structure 110 and configured to bond mesa structure 110 with IC backplane 140. With the group of bottom connecting structures 150, each mesa structure 110 can be controlled independently.

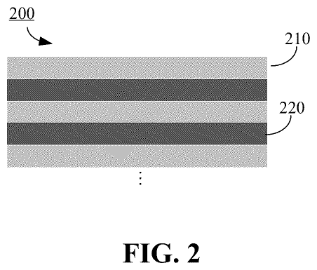

In some embodiments, reflective isolation layer 130 comprises a dielectric distributed Bragg reflection (DBR) structure. FIG. 2 illustrates a structural diagram showing an exemplary DBR structure 200, according to some embodiments of the present disclosure. As shown in FIG. 2, DBR structure 200 includes a plurality of first layers 210 and a plurality of second layers 220, the plurality of first layers 210 and the plurality of second layers 220 being alternately layered. In some embodiments, materials of the plurality of first layers 210 and the plurality of second layers 220 are SiO₂ and TiO₂, respectively. With DBR structure 200, reflective isolation layer 130 may have a high reflectivity and prevent metal migration, thereby improving display brightness.

In some embodiments, a thickness of one first layer 210 or a thickness of one second layer 220 can be adjusted according to a wavelength of light emitted by micro LED display panel 100. For example, the thickness of one first layer 210 or the thickness of one second layer 220 is λ/4, wherein λ represents a wavelength of light emitted by micro LED display panel 100. A total thickness of DBR structure 200, e.g., a thickness of reflection isolation layer 130 is in a range of 0.3 μm to 5 μm. By adjusting a thickness of DBR structure 200 according to the wavelength of light emitted by micro LED display panel 100, a reflectivity of DBR structure 200 is increased, for example, more than 99%, thereby improving the light emitting efficiency.

In some embodiments, top transparent conductive layer 120 is selected from one of TCO (transparent conductive oxide) layers, for example, an ITO (Indium Tin Oxide) layer, an AZO (Antimony doped Zinc Oxide) layer, an ATO (Antimony doped Tin Oxide) layer, an FTO (Fluorine doped Tin Oxide) layer, and the like.

In some embodiments, bottom connecting structure 150 is a metal via. A material of the metal via is TiCu or Cu. Bottom connecting structure 150 is connected with a bottom pad 141 of IC backplane 140.

In some embodiments, micro LED display panel 100 further includes a micro lens array 160 corresponding to the mesa array. Micro lens array 160 is formed on top transparent conductive layer 120. A material of micro lens array 160 is selected from one or more of SiO₂, Si₃N₄, or Al₂O₃.

In some embodiments, micro lens array 160 includes a bottom spacer 161 formed on a top surface of top transparent conductive layer 120, and a plurality of micro lens structures 162 formed on bottom spacer 161. The plurality of micro lens structures 162 correspond to the plurality of mesa structures 110. In some embodiments bottom spacer 161 and the plurality of micro lens structures 162 are an integrated structure, that it, micro lens structure 162 can be etched from micro lens array 160. Materials of bottom spacer 161 and the plurality of micro lens structures 162 are the same. By adjusting a thickness of bottom spacer 161 and a height of micro lens structure 162, light emission efficiency can be further improved. In some embodiments, micro lens structure 162 is semi-spherical, conical, pyramidal, cylindrical, or circular truncated conical. A height H of micro lens structure 162 is in a range of 0.05 μm to 10 μm, and a diameter D of a bottom cross section of micro lens structure 162 is in a range of 0.5 μm to 10 μm.

Referring to FIG. 1, in some embodiments, mesa structure 110 includes a first type epitaxial layer 111, a light emitting layer 112, and a second type epitaxial layer 113. First type epitaxial layer 111 is formed on a top surface of bottom connecting structure 150. Light emitting layer 112 is formed on first type epitaxial layer 111, and second type epitaxial layer 113 is formed on light emitting layer 112. First type epitaxial layer 111 is a P-type epitaxial layer or an N-type epitaxial layer. A material of first type epitaxial layer 111 is one or more of GaN, AlGaN, GaP, AlGaInP, or AlInP. Light emitting layer 112 is a quantum well layer. A material of light emitting layer 112 is selected from one or more of InGaN, AlGaN, or AlGaInP. Second type epitaxial layer 113 is an N-type epitaxial layer or a P-type epitaxial layer. First type epitaxial layer 111 and second type epitaxial layer 113 have opposite conductively types. That is, if first type epitaxial layer 111 is a P-type epitaxial layer, second type epitaxial layer 113 is an N-type epitaxial layer; if first type epitaxial layer 111 is an N-type epitaxial layer, second type epitaxial layer 113 is a P-type epitaxial layer. A material of second type epitaxial layer 113 is selected from one or more of AlInP, AlGaInP, GaN, or AlGaN.

In some embodiments, second type epitaxial layer 113 includes an extrusion portion 113A formed on reflective isolation layer 130 and extending along a top surface of reflective isolation layer 130. Extrusion portion 113A interconnects second type epitaxial layers 113 of adjacent mesa structure 110 of the mesa array. A top surface of second type epitaxial layer 113 is continuously formed on the mesa array. Top transparent conductive layer 120 is continuously formed on the top surface of second type epitaxial layer 113. Therefore, top transparent conductive layer 120 can connect all the mesa structures 110 in micro LED display panel 100 and provide electrical conductivity for mesa structures 110.

Referring back to FIG. 1, in some embodiments, micro LED display panel 100 further includes a plurality of top contacts 170. Each top contact 170 is formed on a surface of top transparent conductive layer 120 between adjacent mesa structures 110. A material of top contact 170 is metal, for example, one or more of Cr, Al, Ti, Pt, Au, Ag, Ni, Ge, or Sn.

In some embodiments, micro LED display panel 100 further include an electrode pad 180 formed on an edge of the mesa array. Electrode pad 180 is connected with top transparent conductive layer 120. In some embodiments, electrode pad 180 is formed on a sidewall surface of top transparent conductive layer 120. A top of electrode pad 180 is higher than a top of top transparent conductive layer 120. In some embodiments, electrode pad 180 and top contact 170 are interconnected, for example, electrode pad 180 and top contact 170 are interconnected to form a mesh, to improve conductive connection performance for top transparent conductive layer 120.

In some embodiments, micro LED display panel 100 further includes a passivation layer 190 formed on a sidewall surface of mesa structure 110. Passivation layer 190 is configured to provide protection for mesa structure 110 during manufacturing. A material of passivation layer 190 is selected from one or more of SiO₂, Si₃N₄, or Al₂O₃.

In some embodiments, passivation layer 190 is further formed on a bottom surface of extrusion portion 113A. In some embodiments, passivation layer 190 is further formed on a top surface of reflective isolation layer 130. Electrode pad 180 is formed on a top surface of passivation layer 130 and on a sidewall surface of extrusion portion 113A. A top of passivation layer 190 is not higher than a top of an end of top transparent conductive layer 120, which can enhance alignment bond adhesion and improve bond yield.

In some embodiments, micro LED display panel 100 further includes one or more IO (Input/Output) vias 191. The one or more IO vias 191 are formed outside the mesa array and throughout reflective isolation layer 130, for example, at an edge of micro LED display panel 100.

In some embodiments, micro LED display panel 100 further includes one or more top connection pads 192 corresponding to one or more IO vias 191. One top connection pad 192 is formed on a top of one IO via 191. One or more bottom connection pads 193 are provided on a top of IC backplane 140. Bottom connection pad 193 can be used for alignment during bonding process. Micro LED display panel 100 further includes a dielectric layer 194 formed on passivation layer 190 and filled in a gap between top connection pads 192.

In some embodiments, bottom pad 141 can be electrically connected with a bottom of one IO via 191. Therefore, bottom pad 141 can be electrically connected with top connection pad 192 through IO via 191.

In some embodiments, electrode pad 180 and top connection pad 192 can be configured to receive a control signal to control micro LED display panel 100. For example, electrode pad 180 and top connection pad 192 can be connected with an external circuit to receive control signals to control each mesa structure 110 independently.

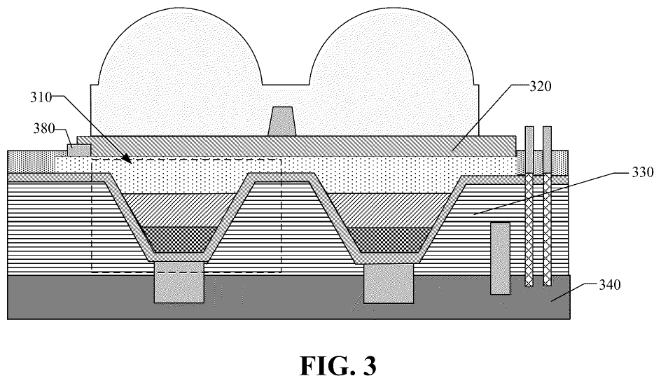

FIG. 3 illustrates a structural diagram showing a sectional view of another micro LED display panel 300, according to some embodiments of the present disclosure. As shown in FIG. 3, micro LED display panel 300 includes one or more mesa structure 310 and an IC backplane 340 formed at a bottom of a reflective isolation layer 330.

Referring to FIG. 3, in this example, an end of a top transparent conductive layer 320 is formed on part of a top of an electrode pad 380 and on a sidewall of electrode pad 380. Electrode pad 380 is provided for connecting to an external circuit.

Description of other features of micro LED display panel 300 may be found by referring to similar features described above with reference to FIG. 1 for micro LED display panel 100, which will not be repeated here.

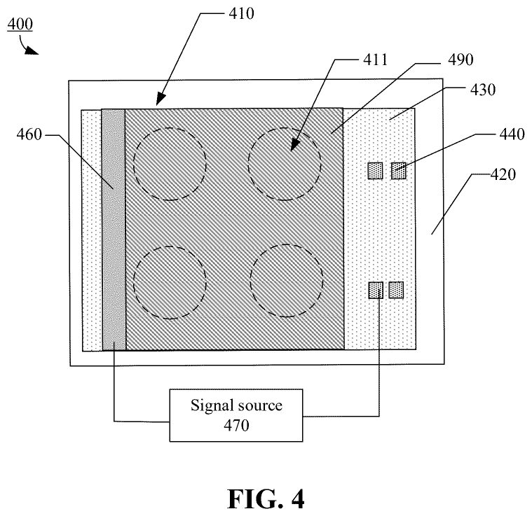

FIG. 4 illustrates a structural diagram showing a top view of micro LED display panel 400, according to some embodiments of the present disclosure. Referring to FIG. 4, micro LED display panel 400 includes a micro LED array area 410 and an IC (integrated circuit) backplane 420 (e.g., IC backplane 140 in FIG. 1 and IC backplane 340 in FIG. 3). Micro LED array area 410 is located on IC backplane 420 to form an image display area of micro LED display panel 400. The rest of the area on IC backplane 420 not covered by micro LED array area 410 is formed as a non-functional area. IC backplane 420 is formed at the back surface of micro LED array area 410 with a part extending outside of, i.e., not covered by, micro LED array area 410. Micro LED array area 410 includes a plurality of micro LED structures 411 (e.g., mesa structures 110 in FIG. 1 and mesa structure 310 in FIG. 3) provided in an array. It can be understood that in FIG. 4, micro LED array area 410 including 2×2 micro structures is showing only for illustrative purpose. IC backplane 420 is configured to control the plurality of micro LED structures 411. IC backplane 420 may include a bottom pad array (not shown) corresponding to micro LED array area 410. The bottom pad array includes a plurality of bottom pads (e.g., bottom pad 141 in FIG. 1) such that one bottom pad corresponds to one micro LED structure 411. One micro LED structure of the plurality of micro LED structures is electrically connected with one bottom pad of the plurality bottom pads.

Each micro LED structure 411 herein (e.g., mesa structure 110 in FIG. 1) has a very small volume. The light emitting area of the micro LED display panel, e.g., micro LED display panel 400 is very small, such as 1 mm×1 mm, 3 mm×5 mm, etc. In some embodiments, the light emitting area is the area of the micro LED array area in the micro LED display panel. Micro LED display panel 400 includes one or more micro LED structure 411 that form a pixel array in which the micro LED structures are pixels, such as a 1600×1200, 680×480, or 1920×1080-pixel array. The diameter of each micro LED is in the range of about 200 nm to 2 μm.

Different types of micro LED panels can be provided. For example, the resolution of a display panel can range typically from 8×8 to 3840×2160. Common display resolutions include QVGA (Quarter Video Graphics Array) with 320×240 resolution and an aspect ratio of 4:3, XGA (Extended Graphics Array) with 1024×768 resolution and an aspect ratio of 4:3, D (Definition) with 1280×720 resolution and an aspect ratio of 16:9, FHD (Full High Definition) with 1920×1080 resolution and an aspect ratio of 16:9, UHD (Ultra High Definition) with 3840×2160 resolution and an aspect ratio of 16:9, and 4K with 4096×2160 resolution. There can also be a wide variety of pixel sizes, ranging from sub-micron and below to 10 mm and above. The size of the overall display region can also vary widely, ranging from diagonals as small as tens of microns or less up to hundreds of inches or more.

The embodiments may further be described using the following clauses:
1. A micro LED display panel, comprising:
a mesa array including a plurality of mesa structures;
a top transparent conductive layer formed on a top surface of the mesa array;
a reflective isolation layer filled in a space between adjacent mesa structures, a bottom of the reflective isolation layer being lower than a bottom of the mesa structure, wherein the reflective isolation layer is a non-metal layer;
an integrated circuit (IC) backplane formed at a bottom of the reflective isolation layer; and
a group of bottom connecting structures, one bottom connecting structure corresponding to one mesa structure, wherein the bottom connecting structure is provided at a bottom of the mesa structure and configured to bond the mesa structure with the IC backplane.
2. The micro LED display panel according to clause 1, wherein the reflective isolation layer comprises a dielectric distributed Bragg reflection (DBR) structure.
3. The micro LED display panel according to clause 2, wherein the DBR structure comprises a plurality of first layers and a plurality of second layers, the plurality of first layers and the plurality of second layers being alternately layered.
4. The micro LED display panel according to clause 3, wherein materials of the plurality of first layers and the plurality of second layers are SiO₂ and TiO₂, respectively.
5. The micro LED display panel according to clause 4, wherein a thickness of the first layer or a thickness of the second layer is λ/4, wherein λ represents a wavelength of light emitted by the micro LED display panel.
6. The micro LED display panel according to clause 5, wherein a thickness of the reflective isolation layer is in a range of 0.3 μm to 5 μm.
7. The micro LED display panel according to clause 1, further comprising a plurality of top contacts, wherein each of the top contacts is formed on a surface of the top transparent conductive layer between adjacent ones of the plurality of mesa structures.
8. The micro LED display panel according to clause 7, wherein a material of the top contact is metal.
9. The micro LED display panel according to clause 1, further comprising:
a micro lens array corresponding to the mesa array, and formed on the top transparent conductive layer.
10. The micro LED display panel according to clause 9, wherein a material of the micro lens array is selected from one or more of SiO₂, Si₃N₄, or Al₂O₃.
11. The micro LED display panel according to clause 9, wherein the micro lens array further comprises:
a bottom spacer formed on a top surface of the top transparent conductive layer; and
a plurality of micro lens structures formed on the bottom spacer.
12. The micro LED display panel according to clause 11, wherein the bottom spacer and the plurality of micro lens structures are an integrated structure.
13. The micro LED display panel according to clause 1, wherein the bottom connecting structure is a metal via.
14. The micro LED display panel according to clause 13, wherein a material of the metal via is TiCu or Cu.
15. The micro LED display panel according to clause 13, wherein the bottom connecting structure is connected with a bottom pad of the IC backplane.
16. The micro LED display panel according to clause 1, wherein the mesa structure comprises:
a first type epitaxial layer formed on a top surface of the bottom connecting structure;
a light emitting layer formed on the first type epitaxial layer; and
a second type epitaxial layer formed on the light emitting layer;
wherein the second type epitaxial layer comprises an extrusion portion formed on the reflective isolation layer and extending along a top surface of the reflective isolation layer.
17. The micro LED display panel according to clause 16, wherein the extrusion portion interconnects second type epitaxial layers of adjacent mesa structure of the mesa array; and a top surface of the second type epitaxial layer is continuously formed on the mesa array.
18. The micro LED display panel according to clause 17, wherein the top transparent conductive layer is continuously formed on the top surface of the second type epitaxial layer.
19. The micro LED display panel according to clause 16, further comprising:
a passivation layer formed on a sidewall surface of the mesa structure and on a bottom surface of the extrusion portion.
20. The micro LED display panel according to clause 19, wherein the passivation layer is further formed on a top surface of the reflective isolation layer, and the micro LED display panel further comprises:
an electrode pad formed on a top surface of the passivation layer and on a sidewall surface of the extrusion portion.
21. The micro LED display panel according to clause 19 or 20, further comprising:
one or more IO (Input/Output) vias, the IO via formed outside the mesa array and through the reflective isolation layer.
22. The micro LED display panel according to clause 21, further comprising:
one or more top connection pads corresponding to the one or more IO vias, wherein one top connection pad is formed on a top of one IO via;
a dielectric layer formed on the passivation layer and filled in a gap between the top connection pads; and
one or more bottom pads provided on the IC backplane corresponding the plurality of mesa structures, wherein a bottom of one IO via is bonded with one bottom pad.
23. The micro LED display panel according to clause 19, a top of the passivation layer is not higher than a top of an end of the top transparent conductive layer.
24. The micro LED display panel according to clause 1, further comprising:
an electrode pad formed on an edge of the mesa array, wherein the electrode pad is connected with the top transparent conductive layer.
25. The micro LED display panel according to clause 24, wherein the electrode pad is formed on a sidewall surface of the top transparent conductive layer.
26. The micro LED display panel according to clause 25, wherein a top of the electrode pad is higher than a top of the top transparent conductive layer.
27. The micro LED display panel according to clause 24, wherein an end of the top transparent conductive layer is formed on part of a top of the electrode pad and on a sidewall of the electrode pad.
28. The micro LED display panel according to clause 1, further comprising:
a passivation layer formed on a sidewall surface of the mesa structure.
29. The micro LED display panel according to clause 28, wherein a material of the passivation layer is selected from one or more of SiO₂, Si₃N₄, or Al₂O₃.
30. The micro LED display panel according to any one of clauses 16 to 29, wherein a material of the first type epitaxial layer is selected from one or more of GaN, AlGaN, GaP, AlGaInP, or AlInP; a material of the second type epitaxial layer is selected from one or more of AlInP, AlGaInP, GaN, or AlGaN; and the light emitting layer is a quantum well layer.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED display panel, comprising:
a mesa array including a plurality of mesa structures;
a top transparent conductive layer formed on a top surface of the mesa array;
a reflective isolation layer filled in a space between adjacent mesa structures, a bottom of the reflective isolation layer being lower than a bottom of the mesa structure, wherein the reflective isolation layer is a non-metal layer;
an integrated circuit (IC) backplane formed at a bottom of the reflective isolation layer; and
a group of bottom connecting structures, one bottom connecting structure corresponding to one mesa structure, wherein the bottom connecting structure is provided at a bottom of the mesa structure and configured to bond the mesa structure with the IC backplane.

2. The micro LED display panel according to claim 1, wherein the reflective isolation layer comprises a dielectric distributed Bragg reflection (DBR) structure.

3. The micro LED display panel according to claim 2, wherein the DBR structure comprises a plurality of first layers and a plurality of second layers, the plurality of first layers and the plurality of second layers being alternately layered.

4. The micro LED display panel according to claim 3, wherein materials of the plurality of first layers and the plurality of second layers are SiO₂ and TiO₂, respectively.

5. The micro LED display panel according to claim 4, wherein a thickness of the first layer or a thickness of the second layer is λ/4, wherein λ represents a wavelength of light emitted by the micro LED display panel.

6. The micro LED display panel according to claim 5, wherein a thickness of the reflective isolation layer is in a range of 0.3 μm to 5 μm.

7. The micro LED display panel according to claim 1, further comprising a plurality of top contacts, wherein each of the top contacts is formed on a surface of the top transparent conductive layer between adjacent ones of the plurality of mesa structures.

8. The micro LED display panel according to claim 7, wherein a material of the top contact is metal.

9. The micro LED display panel according to claim 1, further comprising:
a micro lens array corresponding to the mesa array, and formed on the top transparent conductive layer.

10. The micro LED display panel according to claim 9, wherein a material of the micro lens array is selected from one or more of SiO₂, Si₃N₄, or Al₂O₃.

11. The micro LED display panel according to claim 9, wherein the micro lens array further comprises:
a bottom spacer formed on a top surface of the top transparent conductive layer; and
a plurality of micro lens structures formed on the bottom spacer.

12. The micro LED display panel according to claim 11, wherein the bottom spacer and the plurality of micro lens structures are an integrated structure.

13. The micro LED display panel according to claim 1, wherein the bottom connecting structure is a metal via.

14. The micro LED display panel according to claim 13, wherein a material of the metal via is TiCu or Cu.

15. The micro LED display panel according to claim 13, wherein the bottom connecting structure is connected with a bottom pad of the IC backplane.

16. The micro LED display panel according to claim 1, wherein the mesa structure comprises:
a first type epitaxial layer formed on a top surface of the bottom connecting structure;
a light emitting layer formed on the first type epitaxial layer; and
a second type epitaxial layer formed on the light emitting layer;
wherein the second type epitaxial layer comprises an extrusion portion formed on the reflective isolation layer and extending along a top surface of the reflective isolation layer.

17. The micro LED display panel according to claim 16, wherein the extrusion portion interconnects second type epitaxial layers of adjacent mesa structure of the mesa array; and a top surface of the second type epitaxial layer is continuously formed on the mesa array.

18. The micro LED display panel according to claim 17, wherein the top transparent conductive layer is continuously formed on the top surface of the second type epitaxial layer.

19. The micro LED display panel according to claim 16, further comprising:
a passivation layer formed on a sidewall surface of the mesa structure and on a bottom surface of the extrusion portion.

20. The micro LED display panel according to claim 19, wherein the passivation layer is further formed on a top surface of the reflective isolation layer, and the micro LED display panel further comprises:
an electrode pad formed on a top surface of the passivation layer and on a sidewall surface of the extrusion portion.

21. The micro LED display panel according to claim 19, further comprising:
one or more IO (Input/Output) vias, the IO via formed outside the mesa array and through the reflective isolation layer.

22. The micro LED display panel according to claim 21, further comprising:
one or more top connection pads corresponding to the one or more IO vias, wherein one top connection pad is formed on a top of one IO via;
a dielectric layer formed on the passivation layer and filled in a gap between the top connection pads; and
one or more bottom pads provided on the IC backplane corresponding the plurality of mesa structures, wherein a bottom of one IO via is bonded with one bottom pad.

23. The micro LED display panel according to claim 19, a top of the passivation layer is not higher than a top of an end of the top transparent conductive layer.

24. The micro LED display panel according to claim 1, further comprising:
an electrode pad formed on an edge of the mesa array, wherein the electrode pad is connected with the top transparent conductive layer.

25. The micro LED display panel according to claim 24, wherein the electrode pad is formed on a sidewall surface of the top transparent conductive layer.

26. The micro LED display panel according to claim 25, wherein a top of the electrode pad is higher than a top of the top transparent conductive layer.

27. The micro LED display panel according to claim 24, wherein an end of the top transparent conductive layer is formed on part of a top of the electrode pad and on a sidewall of the electrode pad.

28. The micro LED display panel according to claim 1, further comprising:
a passivation layer formed on a sidewall surface of the mesa structure.

29. The micro LED display panel according to claim 28, wherein a material of the passivation layer is selected from one or more of SiO₂, Si₃N₄, or Al₂O₃.

30. The micro LED display panel according to claim 16, wherein a material of the first type epitaxial layer is selected from one or more of GaN, AlGaN, GaP, AlGaInP, or AlInP; a material of the second type epitaxial layer is selected from one or more of AlInP, AlGaInP, GaN, or AlGaN; and the light emitting layer is a quantum well layer.
